(19) United States
(12) Patent Application Publication
(10) Pub. No.: US 2026/0191064 A1
(43) Pub. Date: Jul. 2, 2026

(54) BOTTOM-UP THROUGH-GLASS VIA PLATING TECHNIQUES

(71) Applicant: Intel Corporation, Santa Clara, CA (US)

(72) Inventors: Wendy Lin, Chandler, AZ (US); Thomas S. Heaton, Mesa, AZ (US); Jieying Kong, Chandler, AZ (US); Ryan Carrazzone, Chandler, AZ (US); Mahdi Mohammadighaleni, Phoenix, AZ (US); Joshua Stacey, Chandler, AZ (US); Ala Omer, Phoenix, AZ (US); Dilan Seneviratne, Phoenix, AZ (US); Gene Coryell, Maricopa, AZ (US); Anqi Zhang, Chandler, AZ (US); Rahul Bhure, Mesa, AZ (US); Tchefor Ndukum, Chandler, AZ (US); Shuqi Lai, Phoenix, AZ (US); Mahdi Raghibi Boroujeni, Tempe, AZ (US); Daniel Rosales-Yeomans, Gilbert, AZ (US); Aaditya Candadai, Chandler, AZ (US); Anand Meled, Chandler, AZ (US); Greg Aponte, Maricopa, AZ (US); Jonathan Glenn, Laveen, AZ (US); Clayton Brenner, Tempe, AZ (US); Srinivas Venkata Ramanuja Pietambaram, Chandler, AZ (US); Emmeline Altschul, Tempe, AZ (US)

(73) Assignee: Intel Corporation, Santa Clara, CA (US)

(21) Appl. No.: 19/004,887

(22) Filed: Dec. 30, 2024

(51) Int. Cl. H01L 23/498; H01L 21/48; H01L 23/15; H01L 23/538

(52) U.S. Cl. CPC H10W 70/69; H10W 70/095; H10W 70/611; H10W 70/635; H10W 70/692

(57) ABSTRACT

Bottom-up through-glass via plating techniques may involve depositing a conductive fill material on a seed material at the bottom of the opening without the need for a seed layer on the sidewalls of the opening. In one example, a layer of adhesive material can be patterned prior to attaching the adhesive to a glass substrate to pre-expose a metallic foil through openings in the adhesive material. In another example, an adhesive film may be bonded to a glass substrate and then patterned prior to bonding with a metallic foil. Bottom-up through-glass via plating may enable the fabrication of conductive vias in a glass substrate with an airgap between the plated conductive material and glass, which may mitigate damage to the glass caused by changes in temperature.

### BACKGROUND

Electronic circuits when commonly fabricated on a wafer of semiconductor material, such as silicon, are called integrated circuits (ICs). The wafer with such ICs is typically cut into numerous individual dies. The dies may be packaged into an IC package containing one or more dies along with other electronic components such as resistors, capacitors, and inductors. The IC package may be integrated onto an electronic system, such as a consumer electronic system, or servers, such as mainframes.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a schematic side, cross-sectional view of one example microelectronic assembly, according to some embodiments of the present disclosure.

FIG. 2 is a schematic side, cross-sectional view of another example microelectronic assembly, according to some embodiments of the present disclosure.

FIGS. 3A and 3B illustrate cross-sectional views of examples of a glass substrate with through-glass vias fabricated using bottom-up plating techniques in accordance with examples described herein.

FIG. 4 is a flow diagram of an example method for fabricating a microelectronic assembly using bottom-up through-glass via plating techniques, in accordance with some embodiments.

FIGS. 5A-5H provide cross-sectional side views at various stages in the fabrication of an example microelectronic assembly according to the method of FIG. 4, in accordance with some embodiments.

FIG. 6 is a flow diagram of an example method for fabricating a microelectronic assembly using bottom-up through-glass via plating techniques, in accordance with some embodiments.

FIGS. 7A-7E provide cross-sectional side views at various stages in the fabrication of an example microelectronic assembly according to the method of FIG. 4, in accordance with some embodiments.

FIG. 8 is a top view of a wafer and dies that may include any of the IC structures disclosed herein, in accordance with any of the embodiments disclosed herein.

FIG. 9 is a side, cross-sectional view of an IC package that may include an assembly or any of the IC structures disclosed herein, in accordance with various embodiments.

FIG. 10 is a side, cross-sectional view of an IC device assembly that may include an assembly or any of the IC structures disclosed herein, in accordance with any of the embodiments disclosed herein.

FIG. 11 is a block diagram of an example electrical device that may include an assembly or any of the IC structures disclosed herein, in accordance with any of the embodiments disclosed herein.

### DETAILED DESCRIPTION

Disclosed herein are integrated circuit (IC) structures and microelectronic assemblies fabricated using bottom-up through-glass via plating techniques. The systems, methods, and devices of this disclosure each have several innovative aspects, no single one of which is solely responsible for all desirable attributes disclosed herein. Details of one or more implementations of the subject matter described in this specification are set forth in the description below and the accompanying drawings.

advanced IC packaging landscape is rapidly evolving to accommodate performance expectations and requirements of shrinking transistor size. Multiple IC dies are now commonly coupled together in a multi-die IC package to integrate features or functionality and to facilitate connections to other components, such as package substrates. Integration of multiple dies in a single IC package has tremendous benefits but adds additional complexities (e.g., due to placing materials with different material properties in close proximity to one another). When an IC package undergoes multiple processing steps involving various temperatures and pressure loads, individual materials within the package may behave differently from one another, resulting in out of plane deformation of various layers, known as “package warpage.” One way to address package warpage is to use stiffer cores to which different IC dies are attached. Recently, glass cores have been explored as alternatives to organic resin-based cores (e.g., cores based on using Ajinomoto Build-up Film (ABF)). Glass is considered more rigid than organic resin-based materials and has several advantages such as excellent thermal properties, low coefficient of thermal expansion (CTE), high electrical insulation, chemical resistance, optical transparency, and compatibility with advances semiconductor properties. However, a major challenge for widespread adoption of glass cores is the fact that glass is highly susceptible to damage due to mechanical and/or thermal stresses, e.g., damage due to stresses caused by through-glass vias (TGVs) filled with metals.

For example, TGVs may be provided in a glass core to route electrical signals in and/or through the glass core. TGVs may also, or alternatively, support efficient thermal management by providing paths for heat dissipation from the active components to the package's external environment. In some implementations, TGVs may extend between the top and the bottom surfaces of a glass core, e.g., to provide electrical connectivity between electronic components such as dies and/or package substrates, coupled to the top and bottom surfaces of the glass core. In other implementations, TGVs may be blind vias that extend from the top/bottom surface of the glass core towards, but not reaching, the opposite surface, e.g., to provide electrical connectivity from a surface of the glass core to a conductive trace or an IC component embedded in the glass core.

Conventionally, the fabrication of TGVs includes forming openings for future TGVs, lining the openings with a seed material, and then depositing a conductive fill material into the lined openings. The seed material typically includes a low-resistivity metal such as copper that can be deposited in a thin layer on substantially non-conductive surfaces (e.g., sidewalls) of openings in a glass core. The seed material is intended to provide conductive surfaces for uniform and controlled deposition of the conductive fill material in a subsequent deposition step, e.g., when the conductive fill material is deposited in the lined openings using a process such as electroplating.

One challenge associated with integration of TGVs in glass cores arises from the differences in CTEs (a phenomenon sometimes referred to as a “CTE mismatch”) between materials that may be used for glass cores and the metals of the seed material and the conductive fill material deposited in the TGVs. CTE is a measure of how a material expands or contracts with changes in temperature. Glass materials that may be used for glass cores and metals have significantly different CTEs. Metals have relatively high CTEs, meaning that they may expand and contract significantly with changes in temperature. Glass materials, on the other hand, have much lower CTEs and are less responsive to temperature changes. For example, a CTE of a glass material may be on the order of about 3.5 ppm/K, while a CTE of a metal such as copper may be on the order of about 15-17 ppm/K. When a metal is in close contact with glass (e.g., a seed material on sidewalls of a TGV in a glass structure), and the assembly is exposed to temperature variations such as heating or cooling, the metal will heat up or cool down much faster, and to a greater extent, than glass. This leads to generation of significant stresses at the interface between the two materials. For example, a metal that is expanding may cause compressive stress, while a metal that is contracting may cause tensile stress. Sufficiently high stress can exceed the strength of glass, leading to formation of cracks which may then propagate and compromise the structural integrity of glass. Even if cracks do not form immediately, the repeated thermal cycling can gradually weaken glass, potentially leading to the development of surface flaws or micro-cracks. Prolonged exposure to CTE mismatch-induced stress can cause gradual degradation of glass, making it more prone to failure over time.

Unlike conventional electroplating techniques that involve depositing a seed layer on sidewalls of a TGV, bottom-up through-glass via plating techniques involve depositing a conductive fill material on a seed material at the bottom of the opening without the need for a seed layer on the sidewalls of the opening. Therefore, unlike conventional plating techniques where a seed layer is on the sidewalls of the opening and the conductive fill material is deposited directly on the seed layer on the sidewalls, bottom-up through-glass via plating can enable the fabrication of conductive vias in a glass substrate with decoupling of plated conductive material and glass (sometimes in the form of air gap(s)). Such an airgap can reduce damage to the glass during changes in temperature by providing a space in which the conductive fill material can expand without resulting in excessive stress on the glass. Some bottom-up plating techniques involve adhering a metallic foil (e.g., a copper foil) to a glass substrate with TGVs using a non-conductive adhesive, and then etching openings in the adhesive to expose the copper at the bottom of the openings. However, etching the non-conductive adhesive at the bottom of TGVs can prove challenging, especially with high aspect ratio TGVs. In contrast, a layer of adhesive material can be patterned prior to attaching the adhesive to the glass substrate to “pre-expose” the metallic foil through openings in the adhesive material.

One such through-glass via plating technique involves providing a layer of an adhesive material over a layer of a first conductive material (e.g., over a metallic foil such as a peelable copper foil or other conductive layer), forming a first opening in the adhesive material to expose the first conductive material, bonding a glass substrate with the layer of adhesive material and the first conductive material, where a second opening in the glass substrate (e.g., a TGV) is at least partially aligned with the first opening in the adhesive, and depositing a second conductive material in the second opening with a bottom-up electroplating process (e.g., using the first conductive material exposed through the first opening as a seed). Thus, in one such example, the adhesive is first attached to the metallic foil, and the adhesive is patterned to expose the metallic foil prior to attaching the glass substrate.

Another through-glass via plating technique involves providing a layer of an adhesive material over a layer of glass with a first opening (e.g., a TGV), forming a second opening through the adhesive material that is at least partially aligned with the first opening, bonding a layer of a first conductive material (e.g., a metallic foil) with the adhesive material and the layer of glass, and depositing a second conductive material in the first opening with a bottom-up electroplating process (e.g., electroplating the second conductive material onto the first conductive material exposed through the first and second openings).

In some examples, an IC structure or assembly fabricated using bottom-up through-glass via plating techniques may include an airgap between the sidewalls of the via and the conductive fill material. For example, an assembly may include a layer of glass having a first face and a second face opposite the first face, a TGV in the layer of glass between the first face to the second face, where the TGV includes a continuous portion of a conductive material between the first face and the second face, and an airgap between the conductive material and the glass at a sidewall of the TGV. Using techniques to clear adhesive at the TGV locations prior to bonding the glass substrate or the foil can mitigate the risks associated with etching the adhesive through the TGV, especially for high aspect ratio structures.

IC structures and microelectronic assemblies fabricated using bottom-up through-glass via plating techniques as described herein may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency IC (RFIC), which may, e.g., be included in any component associated with an IC of an RF receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials, and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations. The terms “substantially,” “close,” “approximately,” “near,” and “about,” generally refer to being within +/−10% of a target value, e.g., within +/−5% of a target value, based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value, e.g., within +/−5% of a target value, based on the context of a particular value as described herein or as known in the art.

In the following description, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

In the drawings, while some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the fabricating processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of an IC structure or microelectronic assembly fabricated using bottom-up through-glass via plating techniques as described herein.

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner. Although some materials may be described in singular form, such materials may include a plurality of materials, e.g., a semiconductor material may include two or more different semiconductor materials.

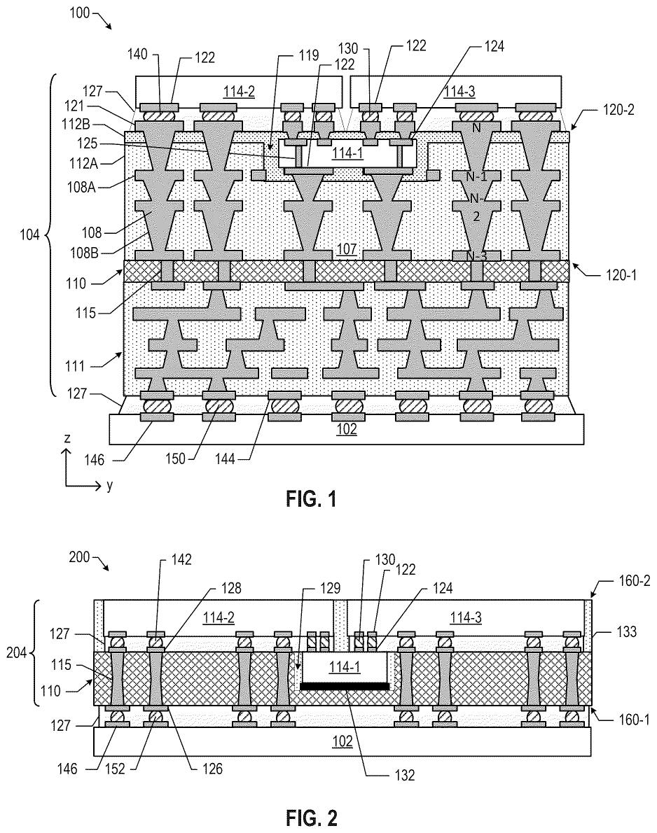

FIG. 1 is a schematic side, cross-sectional view of one example microelectronic assembly 100 that may be fabricated using bottom-up through-glass via plating techniques as described herein, according to some embodiments of the present disclosure. The microelectronic assembly 100 may include a substrate 107 with a double-sided bridge die 1 14-1 in a cavity 119 in the substrate 107, the die 114-1 may be electrically coupled to a conductive pathway, e.g., a conductive trace 108A or a conductive via 108B, in a metal layer of the substrate 107 that is beneath a bottom of the cavity 119. As used herein, the terms “die,” “microelectronic component,” and similar variations may be used interchangeably. As used herein, the terms “interconnect component,” “bridge die,” and similar variations may be used interchangeably. The bridge die 114-1 may be electrically coupled to dies 114-2, 114-3 by die-to-die (DTD) interconnects 130 at a second surface 120-2. In particular, conductive contacts 124 on a top face of the die 114-1 may be coupled to conductive contacts 122 on a bottom face of dies 114-2, 114-3 by conductive vias 108B through the second dielectric material layer 112B. The substrate 107 may include one or more dielectric materials (e.g., a first dielectric material layer 112A and a second dielectric material layer 112B, as shown, together referred to as “one or more layers of dielectric material 112”) and a conductive material 108 arranged in the one or more layers of the dielectric material 112 to provide conductive pathways (e.g., conductive traces 108A and conductive vias 108B) through the substrate 107, as well as to provide conductive pads and contacts. The substrate 107 may include a first surface 120-1 and an opposing second surface 120-2.

As used herein, a “conductive contact” may refer to a portion of conductive material (e.g., metal) serving as an electrical interface between different components (e.g., part of a conductive interconnect); conductive contacts may be recessed in, flush with, or extending away (e.g., having a pillar shape) from a surface of a component, and may take any suitable form (e.g., a conductive pad or socket, or portion of a conductive line or via). In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of a conductive material for providing electrical connectivity to one or more elements associated with the IC or/and between various such elements. In such cases, the term “interconnect” may refer to both conductive traces (also sometimes referred to as “metal traces,” “lines,” “metal lines,” “wires,” “metal wires,” “trenches,” or “metal trenches”) and conductive vias (also sometimes referred to as “vias” or “metal vias”). Sometimes, conductive traces and vias may be referred to as “metal traces” and “metal vias”, respectively, to highlight the fact that these elements include conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PIC. In such cases, the term “interconnect” may refer to optical waveguides (e.g., structures that guide and confine light waves), including optical fiber, optical splitters, optical combiners, optical couplers, and optical vias.

The dies 114-1, 114-2, and 114-3 disclosed herein may include an insulating material (e.g., a dielectric material formed in multiple layers, as known in the art) and multiple conductive pathways formed through the insulating material. In some embodiments, the insulating material of a die (e.g., of dies 114-1, 114-2, 114-3) may include a dielectric material, such as silicon dioxide, silicon nitride, oxynitride, polyimide materials, glass reinforced epoxy matrix materials, or a low-k or ultra low-k dielectric (e.g., carbon-doped dielectrics, fluorine-doped dielectrics, porous dielectrics, organic polymeric dielectrics, photo-imageable dielectrics, and/or benzocyclobutene-based polymers). In some embodiments, the insulating material of the dies 114-1, 114-2, and 114-3 may include a semiconductor material, such as silicon, germanium, or a III-V material (e.g., gallium nitride), and one or more additional materials. For example, an insulating material may include silicon oxide or silicon nitride. The conductive pathways in the dies 114-1, 114-2, and 114-3 may include conductive traces and/or conductive vias, and may connect any of the conductive contacts in the dies 114-1, 114-2, and 114-3 in any suitable manner (e.g., connecting multiple conductive contacts on a same surface or on different surfaces of the dies 114-1, 114-2, and 114-3). Example structures that may be included in the dies 114-1, 114-2, and 114-3 disclosed herein are discussed below with reference to the IC device 1800. The conductive pathways in the dies 114-1, 114-2, 114-3 may be bordered by liner materials, such as adhesion liners and/or barrier liners, as suitable. In some embodiments, one or more of the dies 114-1, 114-2, and 114-3 are wafers. In some embodiments, one or more of the dies 114-1, 114-2, and 114-3 is a monolithic silicon, a fan-out or fan-in package die, or a die stack (e.g., wafer stacked, die stacked, or multi-layer die stacked).

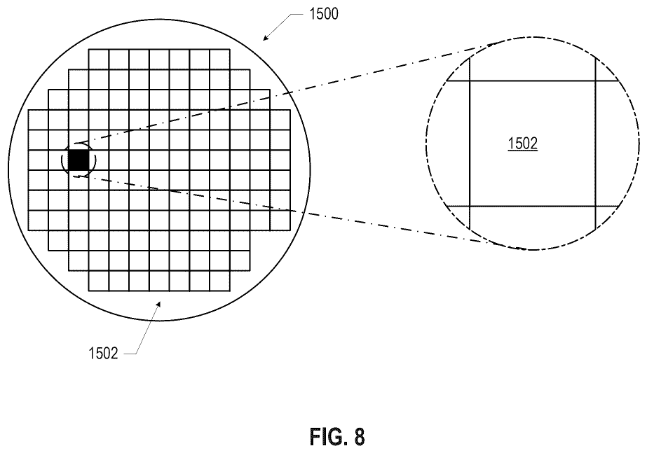

In some embodiments, the 114-1, 114-2, and 114-3 may include conductive pathways to route power, ground, and/or signals to/from other dies 114-1, 114-2, and 114-3 included in the microelectronic assembly 100. For example, the die 114-1 may include TSVs 125, including a conductive via, such as a metal via, isolated from the surrounding silicon or other semiconductor material by a barrier oxide), or other conductive pathways through which power, ground, and/or signals may be transmitted between the package substrate 102 and one or more dies “on top” of the die 114-1 (e.g., in the embodiment of FIG. 1, the dies 114-2 and/or 114-3). In some embodiments, the die 114-1 may not route power and/or ground to the dies 114-2 and 114-3; instead, the dies 114-2, 114-3 may couple directly to power and/or ground lines in the package substrate 102 by substrate-to-package substrate (STPS) interconnects 150, conductive pathways provided by the conductive material 108 in the substrate 107, and die-to-substrate (DTS) interconnects 140. In some embodiments, the die 114-1 may be thicker than the dies 114-2, 114-3. In some embodiments, the die 114-1 may be a memory device or a high frequency serializer and deserializer (SerDes), such as a Peripheral Component Interconnect (PCI) express. In some embodiments, the die 114-1 may be a processing die, a radio frequency chip, a power converter, a network processor, a workload accelerator, a voltage regulator die, or a security encryptor. In some embodiments, the die 114-2 and/or the die 114-3 may be a processing die, a radio frequency chip, a power converter, a network processor, a workload accelerator, a voltage regulator die, or a security encryptor. In some embodiments, the dies 114-1, 114-2, and 114-3 may be as described below with reference to the die 1502 of FIG. 8.

The dielectric material 112 of the substrate 107 may be formed in layers (e.g., at least a first dielectric material layer 112A and a second dielectric material layer 112B). In some embodiments, the dielectric material 112 may include an organic material, such as an organic build-up film. In some embodiments, the dielectric material 112 may include a ceramic, an epoxy film having filler particles therein, glass, an inorganic material, or combinations of organic and inorganic materials, for example. In some embodiments, the conductive material 108 may include a metal (e.g., copper). In some embodiments, the substrate 107 may include layers of dielectric material 112/conductive material 108, with lines/traces/pads/contacts (e.g., conductive traces 108A) of conductive material 108 in one layer electrically coupled to lines/traces/pads/contacts (e.g., conductive traces 108A) of conductive material 108 in an adjacent layer by vias (e.g., 108B) of the conductive material 108 extending through the dielectric material 112. Conductive traces 108A may be referred to herein as “conductive lines,” “conductive elements,” “conductive pads,” or “conductive contacts.” A substrate 107 including such layers may be formed using a printed circuit board (PCB) fabrication technique, for example.

A substrate 107 may include N layers of conductive material 108, where N is an integer greater than or equal to one. In FIG. 1, the layers are labeled in descending order from the second surface 120-2 (e.g., the top face) of the substrate 107 (e.g., layer N, layer N-1, layer N-2, etc.). In particular, as shown in FIG. 1, a substrate 107 may include four metal layers (e.g., N, N-1, N-2, and N-3). The N metal layer may include conductive contacts 121 at the second surface 120-2 of the substrate 107 that are coupled to conductive contacts 122 at bottom faces of the die 114-2, 114-3 by DTS interconnects 140. The N-2 metal layer may include conductive traces 108A having a top face (e.g., the surface facing towards the second surface 120-2 of the substrate 107), an opposing bottom face (e.g., the surface facing towards the first surface 120-1 of the substrate 107), and lateral surfaces extending between the top and bottom faces of the conductive traces 108A. A substrate 107 may further include an N-1 metal layer above the N-2 metal layer and below the N metal layer.

Although a particular number and arrangement of layers of dielectric material 112/conductive material 108 are shown in various ones of the accompanying figures, these particular numbers and arrangements are simply illustrative, and any desired number and arrangement of dielectric material 112/conductive material 108 may be used. Further, although a particular number of layers are shown in the substrate 107 (e.g., four layers), these layers may represent only a portion of the substrate 107, for example, further layers may be present (e.g., layers N-4, N-5, N-6, etc.).

As shown in FIG. 1, the substrate 107 may further include a glass core 110. The glass core 110 may also be referred to as a layer of glass or a glass substrate. Further layers 111 may be present below the glass core 110 and coupled to a package substrate 102 by interconnects 150. As used herein, the term “glass core” refers to a layer (e.g., a glass layer) or a structure (e.g., a portion of a glass layer) of any glass material such as quartz, silica, fused silica, silicate glass (e.g., borosilicate, aluminosilicate, alumino-borosilicate), soda-lime glass, soda-lime silica, borofloat glass, lead borate glass, photosensitive glass, non-photosensitive glass, or ceramic glass. In particular, the glass core 110 may be bulk glass or a solid volume/layer of glass, as opposed to, e.g., materials that may include particles of glass, such as glass fiber reinforced polymers (e.g., substrates/boards constructed of glass fibers and an epoxy binder). Such glass materials are typically non-crystalline, often transparent, amorphous solids. In some embodiments, the glass core 110 may be an amorphous solid glass layer. In some embodiments, the glass core 110 may include a material comprising silicon and oxygen, as well as any one or more of aluminum, boron, magnesium, calcium, barium, tin, sodium, potassium, strontium, phosphorus, zirconium, lithium, titanium, and zinc. In some embodiments, the glass core 110 may include a material, e.g., any of the materials described above, with a weight percentage of silicon being at least about 0.5%, e.g., between about 0.5% and 50%, between about 1% and 48%, or at least about 23%. For example, if the glass core 110 is fused silica, the weight percentage of silicon may be about 47%. In some embodiments, the glass core 110 may include a material having at least 23% silicon and/or at least 26% oxygen by weight, and, in some further embodiments, the glass core 110 may further include at least 5% aluminum by weight. In some embodiments, the glass core 110 may include any of the materials described above and may further include one or more additives such as Al₂O₃, B₂O₃, MgO, CaO, SrO, BaO, SnO₂, Na₂O, K₂O, SrO, P₂O₃, ZrO₂, Li₂O, Ti, and Zn. In some embodiments, the glass core 110 may be a layer of glass that does not include an organic adhesive or an organic material. The glass core 110 may be distinguished from, for example, the “prepreg” or “RF4” core of a PCB substrate which typically includes glass fibers embedded in a resinous organic material such as an epoxy. In such traditional cores/substrates including glass fibers and epoxy, the diameter of the glass fibers is generally in the range of 5 micron to 200 micron. In contrast, the glass core 110 may be a layer of glass that is about 10 millimeters on a side to about 250 millimeters on a side (e.g., 10 millimeters×10 millimeters to 250 millimeters×250 millimeters).

In some embodiments, a cross-section of the glass core 110 in an x-z plane, a y-z plane, and/or an x-y plane of an example coordinate system shown in FIG. 1, may be substantially rectangular (axes shown in subsequent drawings refer to the axes of the coordinate system shown in FIG. 1), although in some further embodiments the glass core 110 may have rounded or beveled edges/sides/sidewalls. In some embodiments, in the top-down view of the glass core 110 (e.g., the x-y plane of the coordinate system shown in FIG. 1), the glass core 110 may have a first length in a range of 10 millimeters to 250 millimeters, and a second length in a range of 10 millimeters to 250 millimeters, the first length perpendicular to the second length. A thickness of the glass core 110 (e.g., a dimension measured along the z axis of the coordinate system of FIG. 1) may be in a range of about 50 micron to 1.4 millimeters. In some embodiments, the glass core 110 may be a glass core substrate, where the glass core substrate has a thickness in a range of about 50 microns to 1.4 millimeters. In some embodiments, the glass core 110 may be a layer of glass comprising a rectangular prism volume, possibly with rounded or beveled edges/sides/sidewalls. In some such embodiments, the rectangular prism volume may have a first side and a second side perpendicular to the first side, the first side having a length in a range of 10 millimeters to 250 millimeters and the second side having a length in a range of 10 millimeters to 250 millimeters. In some embodiments, the glass core 110 may be a rectangular prism volume with sections (e.g., vias) removed and filled with other materials (e.g., metal) e.g., the TGVs 115. In some embodiments, the glass core 110 may be a layer of glass having a thickness in a range of 50 microns to 1.4 millimeters, a first length in a range of 10 millimeters to 250 millimeters, and a second length in a range of 10 millimeters to 250 millimeters, the first length perpendicular to the second length.

In some implementations, together, the substrate 107, including the glass core 110, and the dies 114-1, 114-2, 114-3 may be referred to as a “a multi-layer die subassembly 104.” The glass core 110 may provide mechanical stability to the multi-layer die subassembly 104, the substrate 107, and/or the microelectronic assembly 100. The glass core 110 may reduce warpage and may provide a more robust surface for attachment of the multi-layer die subassembly 104 to a package substrate 102 or other substrate (e.g., an interposer or a circuit board).

In some implementations, together, the dielectric material 112 of the substrate 107 and the glass core 110 may be referred to as a “multi-layer glass substrate.” In some such embodiments, the multi-layer glass substrate may be a coreless substrate. In some such embodiments, the glass core 110 may be a glass layer having a thickness in a range of about 25 microns to 50 microns. In some embodiments, the further layers 111 may also be part of the multi-layer glass substrate.

In the example in FIG. 1, the glass core 110 includes TGVs 115. In the illustrated example, some or all of the TGVs may be or include conductive vias that include a conductive material to form conductive interconnects. For example, the TGVs 115 are conductive vias that may include any appropriate conductive material, e.g., a metal such as copper, silver, nickel, gold, aluminum, or other metals or alloys. The TGVs 115 may be vias extending between a first side and a second side of the glass core 110 (e.g., between the bottom face and the top face of the glass core 110). The openings for the TGVs 115 may be formed using any suitable process, including, for example, a direct laser drilling or laser-induced etching process (which may also be referred to as laser patterning or selective laser activation). In some embodiments, the TGVs 115 disclosed herein may have a pitch between 50 microns and 500 microns, e.g., as measured from a center of one TGV 115 to a center of an adjacent TGV 115. The TGVs 115 may have any suitable size and shape. In some embodiments, the TGVs 115 may have a round (e.g., circular or oval), rectangular, or other shaped cross-section. In some embodiments, at least some of the TGVs 115 may have an hourglass shape (e.g., the TGVs 115 may taper from both sides so that the TGVs have a narrower width between two larger widths). In some embodiments, at least some of the TGVs 115 may taper down from one face of the glass core 110 to another, e.g., from the top face of the glass core 110 to the bottom face of the glass core 110.

The substrate 107 (e.g., further layers 111) may be coupled to a package substrate 102 by STPS interconnects 150. In particular, the top face of the package substrate 102 may include a set of conductive contacts 146. Conductive contacts 144 on the bottom face of the substrate 107 may be electrically and mechanically coupled to the conductive contacts 146 on the top face of the package substrate 102 by the STPS interconnects 150. The package substrate 102 may include an insulating material (e.g., a dielectric material formed in multiple layers, as known in the art) and one or more conductive pathways to route power, ground, and signals through the dielectric material (e.g., including conductive traces and/or conductive vias, as shown). In some embodiments, the insulating material of the package substrate 102 may be a dielectric material, such as an organic dielectric material, a fire retardant grade 4 material (FR-4), bismaleimide triazine (BT) resin, polyimide materials, glass reinforced epoxy matrix materials, organic dielectrics with inorganic fillers or low-k and ultra low-k dielectric (e.g., carbon-doped dielectrics, fluorine-doped dielectrics, porous dielectrics, and organic polymeric dielectrics). In particular, when the package substrate 102 is formed using standard PCB processes, the package substrate 102 may include FR-4, and the conductive pathways in the package substrate 102 may be formed by patterned sheets of copper separated by build-up layers of the FR-4. The conductive pathways in the package substrate 102 may be bordered by liner materials, such as adhesion liners and/or barrier liners, as suitable. In some embodiments, the package substrate 102 may be formed using a lithographically defined via packaging process. In some embodiments, the package substrate 102 may be manufactured using standard organic package manufacturing processes, and thus the package substrate 102 may take the form of an organic package. In some embodiments, the package substrate 102 may be a set of redistribution layers formed on a panel carrier by laminating or spinning on a dielectric material, and creating conductive vias and lines by laser drilling and plating. In some embodiments, the package substrate 102 may be formed on a removable carrier using any suitable technique, such as a redistribution layer technique. Any method known in the art for fabrication of the package substrate 102 may be used, and for the sake of brevity, such methods will not be discussed in further detail herein.

In some embodiments, the package substrate 102 may be a lower density medium and the dies 114-1, 114-2, 114-3 may be a higher density medium or have an area with a higher density medium. As used herein, the terms “lower density” and “higher density” are relative terms indicating that the conductive pathways (e.g., including conductive interconnects, conductive lines, and conductive vias) in a lower density medium are larger and/or have a greater pitch than the conductive pathways in a higher density medium. In some embodiments, a higher density medium may be manufactured using a modified semi-additive process or a semi-additive build-up process with advanced lithography (with small vertical interconnect features formed by advanced laser or lithography processes), while a lower density medium may be a PCB manufactured using a standard PCB process (e.g., a standard subtractive process using etch chemistry to remove areas of unwanted copper, and with coarse vertical interconnect features formed by a standard laser process). In other embodiments, the higher density medium may be manufactured using semiconductor fabrication process, such as a single damascene process or a dual-damascene process. In some embodiments, additional dies may be disposed on the top face of the dies 114-2, 114-3. In some embodiments, additional components may be disposed on the top face of the dies 114-2, 114-3. Additional passive components, such as surface-mount resistors, capacitors, and/or inductors, may be disposed on the top face or the bottom face of the package substrate 102, or embedded in the package substrate 102.

The microelectronic assembly 100 of FIG. 1 may also include an underfill material 127. In some embodiments, the underfill material 127 may extend between the substrate 107 and the package substrate 102 around the associated STPS interconnects 150. In some embodiments, the underfill material 127 may extend between different ones of the top level dies 114-2, 114-3 and the top face of the substrate 107 around the associated DTS interconnects 140 and between the bridge die 114-1 and the top level dies 114-2, 114-3 around the DTD interconnects 130. The underfill material 127 may be an insulating material, such as an appropriate epoxy material. In some embodiments, the underfill material 127 may include a capillary underfill, non-conductive film (NCF), or molded underfill. In some embodiments, the underfill material 127 may include an epoxy flux that assists with soldering the multi-layer die subassembly 104 to the package substrate 102 when forming the STPS interconnects 150, and then polymerizes and encapsulates the STPS interconnects 150. The underfill material 127 may be selected to have a CTE that may mitigate or minimize the stress between the substrate 107 and the package substrate 102 arising from uneven thermal expansion in the microelectronic assembly 100. In some embodiments, the CTE of the underfill material 127 may have a value that is intermediate to the CTE of the package substrate 102 (e.g., the CTE of the dielectric material of the package substrate 102) and a CTE of the dies 114-1, 114-2, 114-3 and/or dielectric material 112 of the substrate 107.

The STPS interconnects 150 disclosed herein may take any suitable form. In some embodiments, a set of STPS interconnects 150 may include solder (e.g., solder bumps or balls that are subject to a thermal reflow to form the STPS interconnects 150), for example, as shown in FIG. 1, the STPS interconnects 150 may include solder between a conductive contacts 144 on a bottom face of the substrate 107 and a conductive contact 146 on a top face of the package substrate 102. In some embodiments, a set of STPS interconnects 150 may include an anisotropic conductive material, such as an anisotropic conductive film or an anisotropic conductive paste. An anisotropic conductive material may include conductive materials dispersed in a non-conductive material.

The DTD interconnects 130 disclosed herein may take any suitable form. The DTD interconnects 130 may have a finer pitch than the STPS interconnects 150 in a microelectronic assembly. In some embodiments, the dies 114-1, 114-2, 114-3 on either side of a set of DTD interconnects 130 may be unpackaged dies, and/or the DTD interconnects 130 may include small conductive bumps (e.g., copper bumps). The DTD interconnects 130 may have too fine a pitch to couple to the package substrate 102 directly (e.g., too fine to serve as DTS interconnects 140 or STPS interconnects 150). In some embodiments, a set of DTD interconnects 130 may include solder. In some embodiments, a set of DTD interconnects 130 may include an anisotropic conductive material, such as any of the materials discussed above. In some embodiments, the DTD interconnects 130 may be used as data transfer lanes, while the STPS interconnects 150 may be used for power and ground lines, among others. In some embodiments, some or all of the DTD interconnects 130 in a microelectronic assembly 100 may be metal-to-metal interconnects (e.g., copper-to-copper interconnects, or plated interconnects). In such embodiments, the DTD interconnect 130 may be bonded together (e.g., under elevated pressure and/or temperature) without the use of intervening solder or an anisotropic conductive material. Any of the conductive contacts disclosed herein (e.g., the conductive contacts 122, 124, 144, and/or 146) may include bond pads, solder bumps, conductive posts, or any other suitable conductive contact, for example. In some embodiments, some or all of the DTD interconnects 130 and/or the DTS interconnects 140 in a microelectronic assembly 100 may be solder interconnects that include a solder with a higher melting point than a solder included in some or all of the STPS interconnects 150. For example, when the DTD interconnects 130 and the DTS interconnects 140 in a microelectronic assembly 100 are formed before the STPS interconnects 150 are formed, solder-based DTD interconnects 130 and DTS interconnects 140 may use a higher-temperature solder (e.g., with a melting point above 200 degrees Celsius), while the STPS interconnects 150 may use a lower-temperature solder (e.g., with a melting point below 200 degrees Celsius). In some embodiments, a higher-temperature solder may include tin; tin and gold; or tin, silver, and copper (e.g., 96.5 % tin, 3% silver, and 0.5% copper). In some embodiments, a lower-temperature solder may include tin and bismuth (e.g., eutectic tin bismuth) or tin, silver, and bismuth. In some embodiments, a lower-temperature solder may include indium, indium and tin, or gallium.

In the microelectronic assemblies 100 disclosed herein, some or all of the DTS interconnects 140 and the STPS interconnects 150 may have a larger pitch than some or all of the DTD interconnects 130. DTD interconnects 130 may have a smaller pitch than STPS interconnects 150 due to the greater similarity of materials in the different dies 114-1, 114-2, 114-3 on either side of a set of DTD interconnects 130 than between the substrate 107 and the top level dies 114-2, 114-3 on either side of a set of DTS interconnects 140, and between the substrate 107 and the package substrate 102 on either side of a set of STPS interconnects 150. In particular, the differences in the material composition of a substrate 107 and a die (e.g., one or more of the dies 114-1, 114-2, 114-3) or a package substrate 102 may result in differential expansion and contraction due to heat generated during operation (as well as the heat applied during various manufacturing operations). To mitigate damage caused by this differential expansion and contraction (e.g., cracking, solder bridging, etc.), the DTS interconnects 140 and the STPS interconnects 150 may be formed larger and farther apart than DTD interconnects 130, which may experience less thermal stress due to the greater material similarity of the pair of dies on either side of the DTD interconnects. In some embodiments, the DTS interconnects 140 disclosed herein may have a pitch between 25 microns and 250 microns. In some embodiments, the STPS interconnects 150 disclosed herein may have a pitch between 55 microns and 1000 microns, while the DTD interconnects 130 disclosed herein may have a pitch between 25 microns and 100 microns.

The microelectronic assembly 100 of FIG. 1 may also include a circuit board (not shown). The package substrate 102 may be coupled to the circuit board by second-level interconnects at the bottom face of the package substrate 102. The second-level interconnects may be any suitable second-level interconnects, including solder balls for a ball grid array arrangement, pins in a pin grid array arrangement or lands in a land grid array arrangement. The circuit board may be a motherboard, for example, and may have other components attached to it. The circuit board may include conductive pathways and other conductive contacts for routing power, ground, and signals through the circuit board, as known in the art. In some embodiments, the second-level interconnects may not couple the package substrate 102 to a circuit board, but may instead couple the package substrate 102 to another IC package, an interposer, or any other suitable component. In some embodiments, the substrate 107 may not be coupled to a package substrate 102, but may instead be coupled to a circuit board, such as a PCB.

Although FIG. 1 depicts a microelectronic assembly 100 having a substrate with a particular number of dies and conductive pathways provided by the conductive material 108 coupled to other dies, this number and arrangement are simply illustrative, and a microelectronic assembly 100 may include any desired number and arrangement of dies. Although FIG. 1 shows the die 114-1 as a double-sided die and the dies 114-2, 114-3 as single-sided dies, the dies 114-2, 114-3 may be double-sided dies and the die 114-1 may be a single-pitch die or a mixed-pitch die. In some embodiments, additional components may be disposed on the top face of the dies 114-2 and/or 114-3. In this context, a double-sided die refers to a die that has connections on both surfaces. In some embodiments, a double-sided die may include through TSVs to form connections on both surfaces. The active surface of a double-sided die, which is the surface containing one or more active devices and a majority of interconnects, may face either direction depending on the design and electrical requirements.

Further, various elements are illustrated in FIG. 1 as included in the microelectronic assembly 100, but, in various embodiments, some of these elements may not be included. For example, in various embodiments, the further layers 111, the underfill material 127, and the package substrate 102 may not be present in the microelectronic assembly 100. In some embodiments, individual ones of the microelectronic assemblies 100 disclosed herein may serve as a system-in-package (SiP) in which multiple dies 114-1, 114-2, 114-3 having different functionality are included. In such embodiments, the microelectronic assembly 100 may be referred to as an SiP.

FIG. 2 is a schematic cross-sectional view of another example microelectronic assembly 200 according to some embodiments of the present disclosure. The configuration of the embodiment shown in the figure is like that of FIG. 1, except for differences as described further. Instead of including the glass core 110 as a part of the substrate 107, as was shown in FIG. 1, the microelectronic assembly 200 of FIG. 2 includes a glass core 110 on its own, where one or more dies may be coupled to the glass core 110. In FIG. 2, the multi-layer die subassembly 204 includes the glass core 110 and the plurality of dies as described above. The multi-layer die subassembly 204 may have a first surface 160-1 (e.g., the bottom face) and an opposing second surface 160-2 (e.g., the top face). The glass core 110 may provide mechanical stability to the multi-layer die subassembly 204 and/or the microelectronic assembly 200 of FIG. 2, may reduce warpage, and may provide a more robust surface for attachment of the multi-layer die subassembly 204 to a package substrate 102 or other substrate (e.g., an interposer or a circuit board).

The glass core 110 may include a cavity 129 with an opening facing the second surface 160-2 and the die 114-1 may be nested, fully or at least partially, in the cavity 129. As shown in FIG. 2, in cases where the die 114-1 is fully nested in a cavity 129, a top face of the die 114-1 may be planar with or below a top face of the glass core 110. In cases where the die 114-1 is partially nested in a cavity 129, a top face of the die 114-1 may extend above a top face of the glass core 110. The cavity 129 may be at least partially filled with a dielectric material 112A or 112B, described above. The die 114-1 may be attached to a bottom face of the cavity 129 by a die-attach film (DAF) 132. A DAF 132 may be any suitable material, including a non-conductive adhesive, die-attach film, a B-stage underfill, or a polymer film with adhesive property. A DAF 132 may have any suitable dimensions, for example, in some embodiments, a DAF 132 may have a thickness (e.g., height or z-height) between 5 microns and 10 microns.

The die 114-1 may be coupled to the dies 114-2, 114-3 in a layer above the die 114-1 through the DTD interconnects 130. The DTD interconnects 130 may be disposed between some of the conductive contacts 122 at the bottom of the dies 114-2, 114-3 and some of the conductive contacts 124 at the top of the die 114-1. Some other conductive contacts 122 at the bottom of the dies 114-2 and/or 114-3 may further couple one or more of the dies 114-2, 114-3 to the glass core 110 by glass core-to-die (GCTD) interconnects 142. The GCTD interconnects 142 may be disposed between some of the conductive contacts 122 at the bottom of the dies 114-2, 114-3 and some of the conductive contacts 128 at the top of the glass core 110. The GCTD interconnects 142 may be similar to the DTS interconnects 140, described above. In some embodiments, the underfill material 127 may extend between different ones of the dies 114 around the associated DTD interconnects 130 and/or GCTD interconnects 142. In some embodiments, a die 114-2 and/or a die 114-3 may be embedded in an insulating material 133. In some embodiments, an overall thickness (e.g., a z-height) of the insulating material 133 may be between 200 microns and 800 microns (e.g., substantially equal to a thickness of die 114-2 or 114-3 and the underfill material 127). In some embodiments, the insulating material 133 may form multiple layers (e.g., a dielectric material formed in multiple layers, as known in the art) and may embed one or more dies 114 in a layer. In some embodiments, the insulating material 133 may be a dielectric material, such as an organic dielectric material, a fire retardant grade 4 material (FR-4), BT resin, polyimide materials, glass reinforced epoxy matrix materials, or low-k and ultra low-k dielectric (e.g., carbon-doped dielectrics, fluorine-doped dielectrics, porous dielectrics, and organic polymeric dielectrics). In some embodiments, the insulating material 133 may be a mold material, such as an organic polymer with inorganic silica particles.

As shown in FIG. 2, the glass core 110 may further include conductive contacts 126 at the bottom of the glass core 110, and TGVs 115 may extend between and electrically couple conductive contacts 126 at the bottom of the glass core 110 and conductive contacts 128 at the top of the glass core 110. The conductive contacts 126, 128 may be similar to other conductive contacts disclosed herein (e.g., the conductive contacts 122, 124, 144, and/or 146), and may include bond pads, solder bumps, conductive posts, or any other suitable conductive contact, for example. As shown in FIG. 2, in some embodiments, at least some of the TGVs 115 may have an hourglass shape. For example, at least some of the TGVs 115 may has a first width at the first face of the glass core 110 (e.g., at the bottom face of the glass core 110), a second width at the second face of the glass core 110 (e.g., at the top face of the glass core 110), and a third width between the first face and the second face of the glass core 110, where the third width is smaller than the first width and the second width.

The dies 114-2, 114-3 may be electrically coupled to the package substrate 102 through the TGVs 115 and glass core-to-package substrate (GCTPS) interconnects 152, which may be power delivery interconnects or high-speed signal interconnects. The GCTPS interconnects 152 may be similar to the STPS interconnects 150, described above. The top face of the package substrate 102 may include a set of conductive contacts 146, the multi-layer die subassembly 204 may include a set of conductive contacts 126 on the first surface 160-1, and the GCTPS interconnects 152 may be between, and couple the conductive contacts 146 with corresponding ones of the conductive contacts 126. In some embodiments, the underfill material 127 may extend between the glass core 110 and the package substrate 102 around the associated GCTPS interconnects 152.

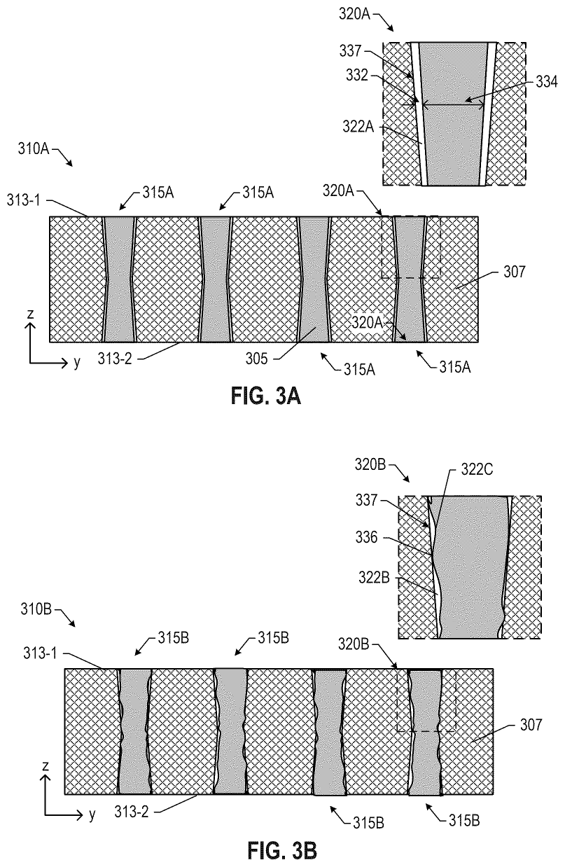

FIGS. 3A and 3B illustrate cross-sectional views of examples of glass substrates with through-glass vias fabricated using bottom-up plating techniques in accordance with examples described herein.

Turning first to FIG. 3A, the glass substrate 310A includes a layer of glass 307, where the layer of glass 307 has a first side or face 313-1 and a second side or face 313-2. The layer of glass 307 may be, for example, a glass core. In other examples, a different core material may be present in the assembly (e.g., ceramic, epoxy, or another core material). Conductive vias 315A extend through the layer of glass 307. The conductive vias 315A include a conductive material 305, which may substantially fill the via openings through the glass 307. As can be seen in FIG. 3A, a continuous portion of the conductive material 305 is between the first face 313-1 and the second face 313-2. In one example, the conductive material 305 may be any suitable electrically conductive material, such as a material including a metal. In one example, the conductive material 305 may be or include copper. The conductive material 305 may be a plated conductive material deposited using a through-glass via bottom-up plating technique in accordance with examples described herein. As a result of using a through-glass via bottom-up plating technique, a seed layer is absent from the sidewalls of the TGVs, and one or more voids or airgaps may be present along the sidewalls of the TGVs between the glass 307 and the plated conductive material (e.g., the conductive material 305).

For example, an airgap 322A between the conductive material 305 and the glass 307 at a sidewall 337 of the TGV are shown in the close-up cross-sectional view of a region 320A (identified in FIG. 3A with a dashed line box). In one example, the airgap 322A may be a region that is devoid of solid material. The airgap 322A may include minimal or no material, or the airgap 322A may be filled with a gaseous substance, e.g., air, nitrogen gas, and/or a different gas. The airgap 322A may also be referred to as a void.

The conductive material 305 (e.g., a continuous portion of the conductive material 305) may have a width 334 in the range of about 50 to 500 micrometers (microns), or about 50 to 150 micrometers. According to examples, the airgap 322A may have a width 332 in a range of 20 to 100 nanometers, about 25 to 60 nanometers, about 25 to 50 nanometers, or about 30 to 45 nanometers, where the width 332 is a dimension of the airgap 322A in a plane substantially parallel with the layer of glass 307 (e.g., the width 332 is a dimension of the airgap 322A along the y axis shown in FIG. 3A). Thus, in some examples, the conductive material 305 substantially fills the TGV with a small airgap 322A at the sidewalls between the conductive material 305 and the glass 307. Accordingly, in some examples, the conductive material 305 is not in direct contact with the glass 305 in at least some portions along the sidewalls 337, but instead separated by an airgap 322A in those regions. As mentioned above, the conductive vias 315A lacks a seed layer on the sidewalls 337 due to the use of a bottom-up through-glass via plating technique. In one example, other solid materials, such as an adhesion layer (e.g., titanium or another material that enables adhesion of copper to glass) is absent from the conductive via between the conductive material 305 and the glass 307.

In the example illustrated in FIG. 3A, the airgap 322A may be present between the conductive material 305 and the glass 307 around the entire portion of the conductive material 305. For example, in a cross-section of the conductive via 315A in a plane substantially parallel with the layer of glass 307 (e.g., in the x-y plane as shown in FIG. 3A, where the x-axis is going into and coming out of the page), the airgap 322A may surround the conductive material 307. In the example illustrated in FIG. 3A, the airgap 322A is a substantially continuous airgap between the first face 313-1 and the second face 313-2 (e.g., the airgap 322A may extend from the first face 313-1 to the second face 313-2 along the sidewalls 337). In other examples, the airgap may include one or more discontinuities (e.g., areas where the conductive material 307 is in contact with the glass 305). An airgap with discontinuities may alternatively be viewed as multiple airgaps separated by the regions where the conductive material 305 is in contact with the glass 307. FIG. 3B illustrates an example where a void between the conductive fill material in the TGV and the glass 307 includes discontinuities.

As can be seen in FIG. 3B, the glass substrate 310B includes conductive through-glass vias 315B extending through the layer of glass 307. Similar to FIG. 3A, FIG. 3B depicts a close-up cross-sectional view of a region 320B (identified in FIG. 3B with a dashed line box). Unlike the airgap 322A that has substantially the same width 332 along the sidewalls 337, the airgap 322B is more irregular and includes one or more discontinuities, such as the discontinuity 336, where the conductive material 305 is in contact with the glass 307 at a discontinuity. For example, the airgap 322B may be one of multiple airgaps between the first face 313-1 and the second face 313-2 of the layer of glass 307, where the conductive material 305 is in contact with the glass 307 between the airgap 322B and an adjacent airgap (e.g., the airgap 322C). In one such example, the airgap 322B may have different widths in different areas along the sidewalls 337 (with or without discontinuities). Thus, in various examples, the conductive material 305 may be separated from the glass sidewalls 337 by one or more voids between the face 313-1 and the face 313-2, where the voids may be continuous (such as shown in FIG. 3A) or may be less consistent and have discontinuities.

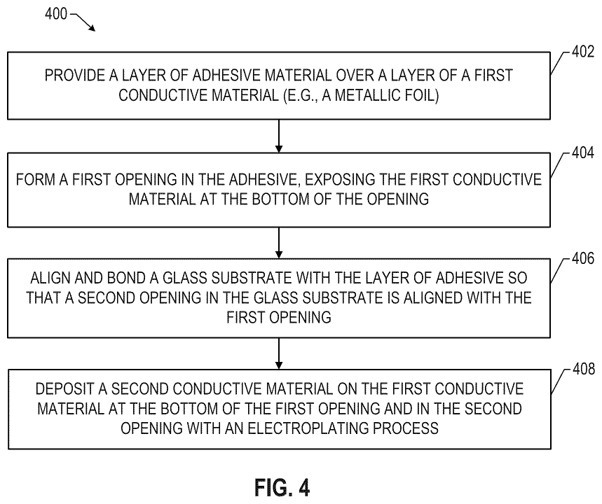

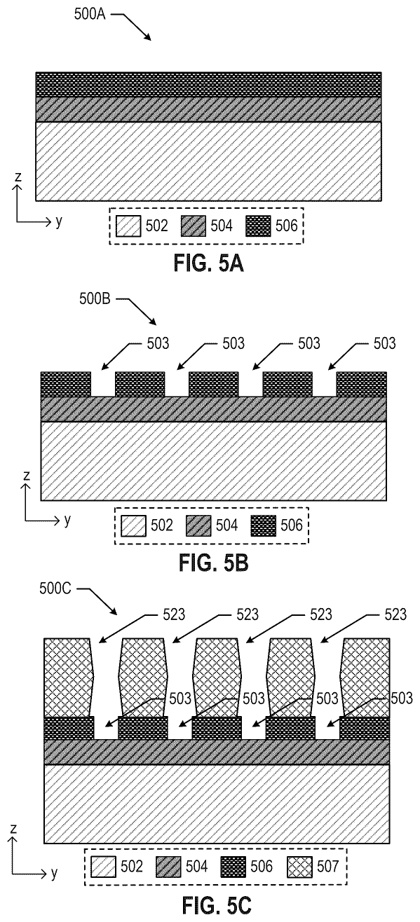

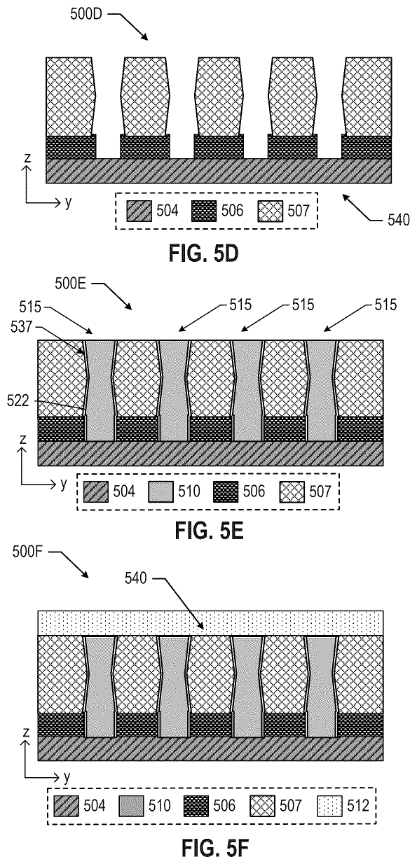

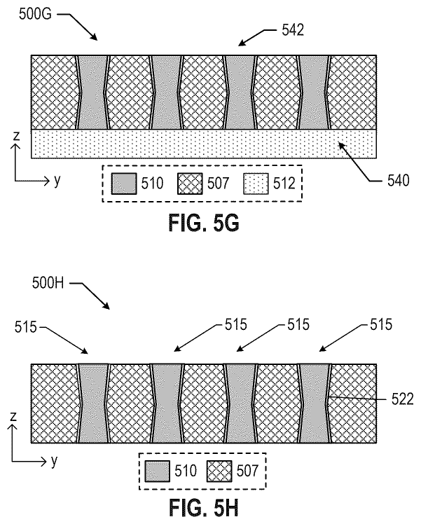

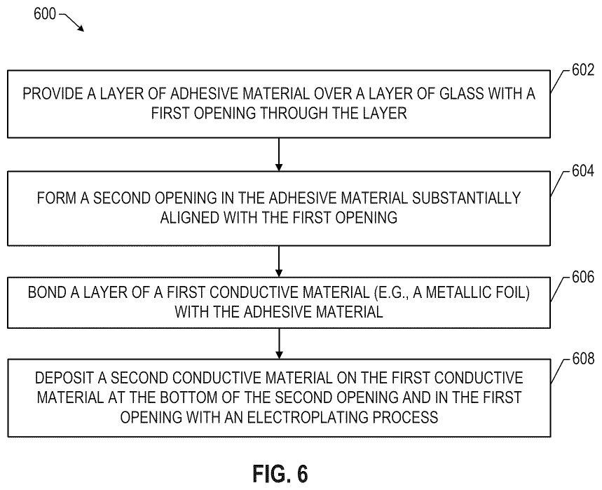

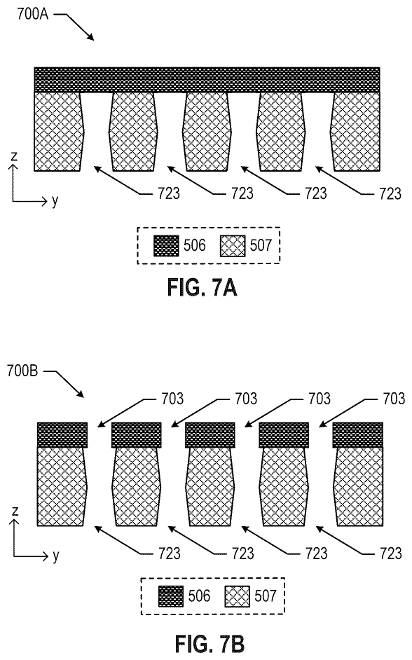

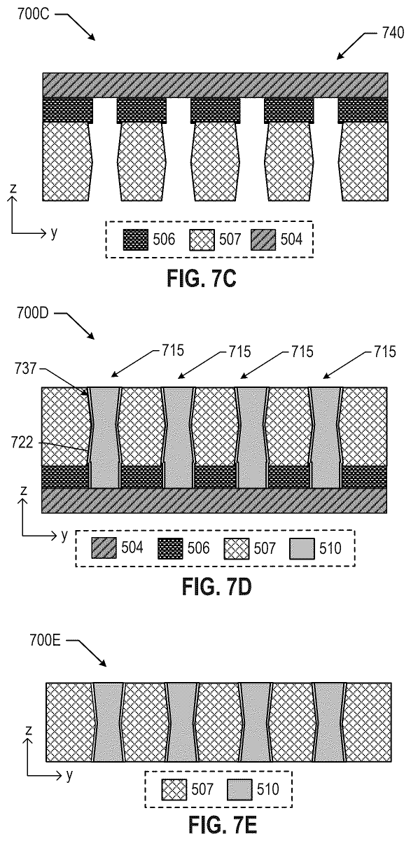

FIGS. 4 and 6 are flow diagrams of example methods 400 and 600 for fabricating IC structures or microelectronic assemblies using bottom-up through-glass via plating techniques. FIGS. 5A-5H provide cross-sectional views along the y-z axis (e.g., the y-z axis as shown in FIGS. 1, 2, and 3A-3B) at various stages in the fabrication of an example microelectronic assembly according to the method of FIG. 4, in accordance with some embodiments. FIGS. 7A-7E provide cross-sectional views along the y-z axis (e.g., the y-z axis as shown in FIGS. 1, 2, and 3A-3B) at various stages in the fabrication of an example microelectronic assembly according to the method of FIG. 6, in accordance with some embodiments. A number of elements referred to in the description of FIGS. 5A-5H and 7A-7E with reference numerals are illustrated in these drawings with different patterns, with a legend showing the correspondence between the reference numerals and patterns being provided at the bottom of each drawing page containing FIGS. 5A-5H and 7A-7E. For example, the legend illustrates that FIG. 5A uses different patterns to show a conductive material 504, an adhesive material 506, and so on.

Although the operations of the methods of FIGS. 4 and 6 are illustrated once each and in a particular order, the operations may be performed in any suitable order and repeated as desired. For example, one or more operations may be performed in parallel to fabricate multiple IC structures or microelectronic assemblies including conductive through-glass vias formed with bottom-up through-glass via plating techniques substantially simultaneously. In another example, the operations may be performed in a different order to reflect the structure in which conductive through-glass vias formed with bottom-up through-glass via plating techniques will be implemented.

In addition, the example fabricating methods of FIGS. 4 and 6 may include other operations not specifically shown in FIGS. 4 and 6, such as various cleaning or planarization operations as known in the art. For example, in some embodiments, a support, as well as layers of various other materials subsequently deposited thereon, may be cleaned prior to, after, or during any of the processes of the methods described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the intermediate IC structures described herein may be planarized prior to, after, or during any of the processes of the methods of FIGS. 4 and 6 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

Turning to FIG. 4, the method 400 begins with a process 402 of providing a layer of adhesive material over a layer of conductive material. The IC structure 500A of FIG. 5A is an example resulting structure of the process 402. The IC structure 500A includes a layer of a conductive material 504 over a carrier or support structure 502, and a layer of an adhesive material 506 over the conductive material 504. In one example, the support structure 502 is a copper clay laminate (CCL) carrier, which is an organic substrate that provides structure for the thin layer of conductive material 504. In one example, the layer of conductive material 504 is a metallic foil, such as a copper foil (where a copper foil includes copper and may also include other elements). In some examples, a metallic foil may be “peelable,” which refers to the ability to peel the metallic foil off of the support structure 502 in order to remove the metallic foil in a subsequent process. The conductive material 504 may have a relatively small thickness (e.g., in the range of about 1 to 5 micrometers, or in the range of about 1.5 to 3.5 micrometers), and may serve as the basis (e.g., seed) upon which a conductive material may be later deposited into TGVs with a bottom-up plating process. The adhesive material 506 may be any material suitable for adhering a layer of glass with the layer of conductive material 504. The layer of adhesive material 506 may be an adhesive film, and may include one or more polymer (e.g., polyimide, polyethylene, polypropylene), epoxy, acrylic, silicone, or other material that may act as an adhesive. In some examples, the adhesive may be a photoresist material (e.g., a photosensitive polyimide film, an epoxy-based photoresist, or other photoresist material). The layer of adhesive may be provided using any suitable technique, such as lamination (e.g., laminating a pre-formed film onto the conductive material 504 and applying heat and pressure), spin-coating, spray coating, slit coating, or another suitable deposition technique.

The method 400 continues with a process 404 of forming an opening in the adhesive material, exposing the conductive material at the bottom of the opening. The IC structure 500B of FIG. 5B is an example resulting structure of the process 404. As can be seen in FIG. 5B, the IC structure 500B includes openings 503 in the adhesive material 506, where the conductive material 504 is exposed at the bottom of the openings 503. In some examples, the width of the openings may be about the same as a width of TGVs in a glass substrate that is subsequently bonded with the adhesive material (where the width of the openings 503 is a dimension of the openings in a plane substantially parallel with the layer of conductive material 504). In other examples, the width of the openings 503 may be smaller than or larger than the corresponding openings in the glass. The openings 503 may be formed using any suitable technique. In one example, a laser drilling process may be used to form the openings 503 in the adhesive material 506. In one such example, and depending on the materials and removal techniques, partial cure of the adhesive may be performed before laser drilling. In another example (e.g., in which a photosensitive adhesive material is used), the openings 503 may be formed using a lithographic process (e.g., patterning and developing the adhesive at approximate TGV locations). Thus, the conductive material 504 has been pre-exposed by patterning the adhesive material 506 prior to bonding a layer of glass with the adhesive material 506.

The method 400 continues with a process 406 of aligning and bonding a glass substrate with the layer of adhesive so that an opening in the glass substrate is aligned with the opening in the adhesive. The IC structure 500C of FIG. 5C is an example resulting structure of the process 406. The IC structure 500C includes a layer of glass 507 bonded with the stack that includes the support structure 502, conductive material 504, and adhesive material 506. The openings 523 (e.g., TGVs) extend through the layer of glass 507, and are substantially aligned with the openings 503 in the adhesive material. In one example, the layer of glass 507 may be bonded with the adhesive material 506 using a lamination process.

The method may then involve removing the support structure 502. The IC structure 500D of FIG. 5D is an example resulting structure of the process of removing the support structure 502. In one example in which the layer of conductive material 504 is a peelable metallic film, removing the support structure may involve a curing process to further bond layers of the stack (e.g., the conductive material 504, adhesive material 506, and glass 507), and peeling away the carrier (e.g., peeling away the support structure 502) from the metallic film post-cure. A film may then be attached to the side 540 of the IC structure 500D with conductive material 504 (e.g., to prevent plating on the side 540 in a subsequent process).

The method 400 continues with a process 408 of depositing a conductive material on the conductive material at the bottom of the first opening and in the second opening with an electroplating process. The IC structure 500E of FIG. 5E is an example resulting structure of the process 408. The IC structure 500E includes a conductive material 510 filling the openings 523 and the openings 503. The conductive material 510 may be deposited with an electroplating process onto the conductive material 504 that is exposed through openings in the adhesive material 506. Thus, the plating process starts at the bottom of the openings 503 and substantially fills the openings 523 from the bottom-up. In some examples, as a result of the bottom-up plating process, airgaps 522 may be present at the sidewalls 537 of the openings 523, such as discussed above with respect to FIGS. 3A-3B. The conductive material 510 may be any suitable conductive material. For example, the conductive material may include one or more metals, such as copper or another suitable metal. After depositing the conductive material 510 with the bottom-up electroplating process, the over-plated conductive material may be removed with a polishing/planarization process. Thus, the IC structure 500E of FIG. 5E includes conductive through-glass vias 515 through the layer of glass 507.

The method may involve the application of a protective film to protect the planarized side 540 of the glass 507 with the conductive through-glass vias 515. The IC structure 500F of FIG. 5F is an example resulting structure of the process of applying a protective film 512 to the polished side 540. The protective film 512 may be, for example, a UV-releasable protective film or any other suitable protective layer, and may be provided over the side 540 using any suitable technique, such as lamination.

The method may then involve flipping over the structure and removing layers of material to expose the conductive material 510 (e.g., with etching and/or polish processes). For example, the method may involve removing a film that was attached to the side 540 of the IC structure prior to electroplating to prevent plating on the side 540, the conductive material 504, the adhesive material 506, and excess portions of the conductive material 510 in the layer with the adhesive material 506. The IC structure 500G of FIG. 5G is an example resulting structure of the process of removing the film applied to prevent electroplating on the side 540, the conductive material 504, the adhesive material 506, and excess portions of the conductive material 510. Removing the conductive material 504 may involve, for example, a wet etch process, or other suitable etch technique. The adhesive material 506 may then be removed, and a planarization process may be used to polish off the remaining protruding portions of the conductive material 510. As can be seen in the example of FIG. 5G, after planarization, the conductive material 510 and the glass 507 are substantially flush with one another on the side 542.

The protective film can then be removed. The IC structure 500H of FIG. 5H is an example resulting structure of the process of removing the protective film 512. The resulting IC structure 500H includes the layer of glass 507, through-glass conductive vias through the layer of glass 507, where the through-glass conductive vias 515 include one or more airgaps between the glass 507 and the conductive material 510 as a result of the bottom-up plating process.

Thus, the method 400 of FIG. 4 illustrates a bottom-up through-glass via plating technique in which the adhesive material is patterned after adhering to a conductive layer (e.g., metallic foil) and prior to bonding with the glass. FIG. 6 illustrates another method 600 of bottom-up through-glass via plating in which the adhesive is patterned after adhering it to the glass, but before adhering the conductive layer.

Turning to FIG. 6, the method 600 begins with a process 602 of providing a layer of adhesive material over a layer of glass with a first opening. The IC structure 700A of FIG. 7A is an example resulting structure of the process 602. The IC structure 700A includes a layer of glass 507 with openings 723. An adhesive material 506 is provided over and bonded with the glass 507. The adhesive material 506 may be provided over and bonded with the glass using any suitable technique, such as those discussed above with respect to the process 402 of the method 400 of FIG. 4.

The method 600 continues with a process 604 of forming an opening in the adhesive material that is substantially aligned with the opening in the layer of glass. The IC structure 700B of FIG. 7B is an example resulting structure of the process 604. As can be seen in FIG. 7B, the IC structure 700B includes openings 703 that are substantially aligned with the openings 723. The openings 703 in the adhesive material 506 may be formed in accordance with any suitable technique (e.g., a laser drilling process).

The method 600 continues with a process 606 of bonding a layer of a conductive material with the layer of adhesive. The IC structure 700C of FIG. 7C is an example resulting structure of the process 606. The IC structure 700C includes a layer of conductive material 506 over and bonded with the adhesive material 506. A film may then be attached to the side 740 of the IC structure 700C with conductive material 504 (e.g., to prevent plating on the side 740 in a subsequent process).

The method 600 continues with a process 608 of depositing a conductive fill material on the conductive material at the bottom of the opening in the adhesive material and in the opening in the glass with an electroplating process. The IC structure 700D of FIG. 7D is an example resulting structure of the process 608. As can be seen in FIG. 7D, the IC structure 700D includes conductive through-glass vias 715 that are substantially filled with the conductive material 510. As a result of performing bottom-up electroplating, the conductive through-glass vias 715 include one or more voids or airgaps 722 between the conductive material 510 and the glass 507.

The IC structure 700D may them be flipped over and etched and/or polished to remove the conductive material 504, the adhesive material 506, and excess portions of the conductive material 510, as shown in FIG. 7E. FIG. 7E illustrates the IC structure 700E after polishing.

Thus, FIGS. 4 and 6 illustrate methods 400 and 600 for fabricating an IC structure or microelectronic assembly using bottom-up through-glass via plating techniques. Performing the methods 400 and 600 may result in several features in the final IC structure or assembly that are characteristic of the use of the methods 400 and 600. For example, one such feature is illustrated in the IC structure 500H of FIG. 5H, in which a glass substrate includes conductive through-glass vias 515 with one or more voids or airgaps 522 are present between the conductive material 510 and the glass 507. Similarly, the IC structure 700E depicts a glass substrate with conductive through-glass vias 715 with one or more voids or airgaps 722 between the conductive material 510 and the glass 507.

IC structures and microelectronic assemblies fabricated using bottom-up through-glass via plating techniques in accordance with techniques described herein may be included in any suitable electronic component or electronic device. FIGS. 8-11 illustrate various examples of apparatuses that may include one or more of the IC structures or assemblies with integrated inductors with conductive polymer separation layers disclosed herein.

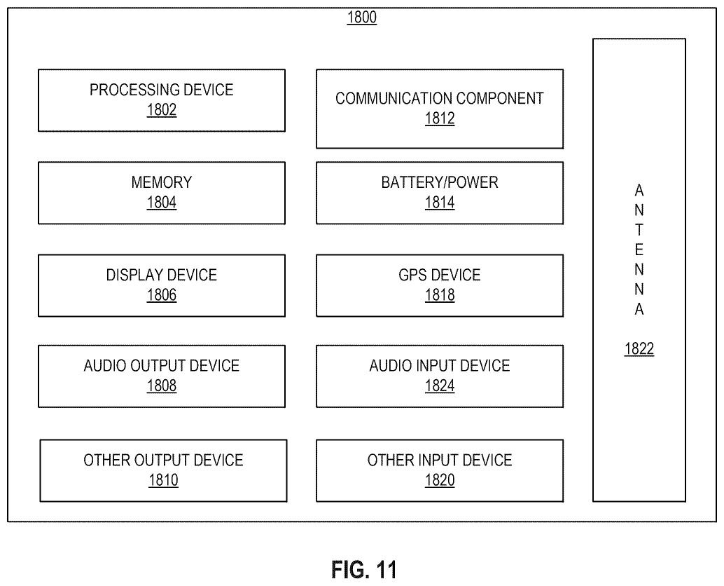

FIG. 8 is a top view of a wafer 1500 and dies 1502 that may include one or more IC structures in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. In some embodiments, the wafer 1500 or the die 1502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 11) or other logic that is configured to store information in the memory devices or execute instructions stored in the memory array.

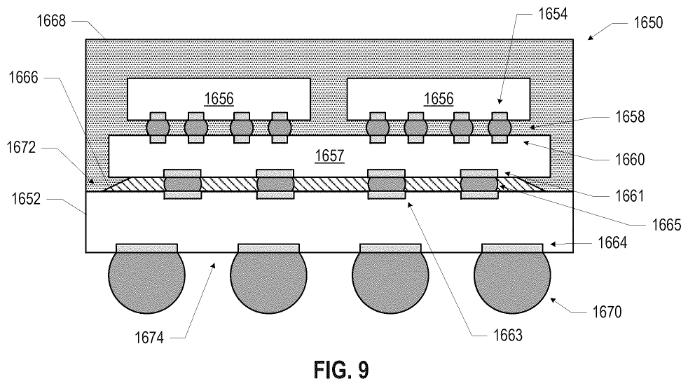

FIG. 9 is a side, cross-sectional view of an example IC package 1650 that may include an assembly or one or more IC structures fabricated using bottom-up through-glass via plating techniques in accordance with any of the embodiments disclosed herein. In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 9 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 9 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

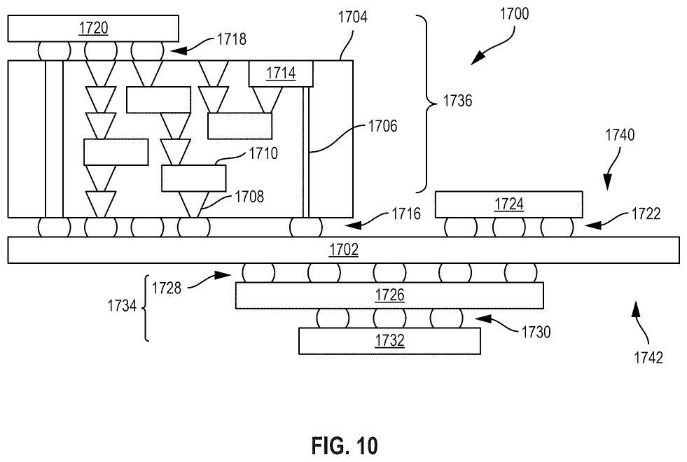

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 9 are solder balls (e.g., for a ball grid array arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 10.

The dies 1656 may take the form of any of the embodiments of the die 1502 discussed herein. In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high bandwidth memory).

Although the IC package 1650 illustrated in FIG. 9 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 9, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 10 is a side, cross-sectional view of an IC device assembly 1700 that may include one or more IC packages or other electronic components (e.g., a die) including an assembly or one or more IC structures fabricated using bottom-up through-glass via plating techniques in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 9 (e.g., may include one or more IC structures in accordance with embodiments described herein).

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 10 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 10), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 10, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 8), an IC device, or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 10, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 10 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 11 is a block diagram of an example electrical device 1800 that may include an assembly or one or more IC structures fabricated using bottom-up through-glass via plating techniques in accordance with any of the embodiments disclosed herein. For example, any suitable ones of the components of the electrical device 1800 may include one or more of the IC device assemblies 1700, IC packages 1650, or dies 1502 disclosed herein. A number of components are illustrated in FIG. 11 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 11, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded DRAM (eDRAM) or spin transfer torque magnetic random access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include another output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include another input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.
Example 1 provides a microelectronic assembly, including a layer of glass having a first face and a second face opposite the first face; and a TGV in the layer between the first face to the second face, where the TGV includes a continuous portion of a conductive material between the first face and the second face, and an airgap between the conductive material and the glass at a sidewall of the TGV.
Example 2 provides the microelectronic assembly of example 1, where: the airgap has a width in a range of about 20 to 100 nanometers, where the width is a dimension of the airgap in a plane substantially parallel with the layer.
Example 3 provides the microelectronic assembly of any one of examples 1-2, where: the airgap includes a substantially continuous airgap between the first face and the second face.
Example 4 provides the microelectronic assembly of any one of examples 1-2, where: the airgap is one of multiple airgaps between the first face and the second face, where the conductive material is in contact with the glass between the airgap and an adjacent airgap.
Example 5 provides the microelectronic assembly of any one of examples 1-4, where: in a cross-section of the TGV in a plane substantially parallel with the layer, the airgap surrounds the conductive material.
Example 6 provides the microelectronic assembly of any one of examples 1-5, where: the TGV lacks a conductive seed layer on the sidewall.
Example 7 provides the microelectronic assembly of any one of examples 1-6, where: a further material (e.g., such as an adhesion promotion layer) is absent from between the sidewall and the conductive material.
Example 8 provides a microelectronic assembly, including a substrate including a layer of glass, where the layer includes a first face and a second face opposite the first face; and a conductive via through the layer, where the conductive via includes a conductive material between the first face and the second face, where the conductive via lacks a seed layer between the conductive material and the glass, and a void between the conductive material and the glass, where the void extends between the first face and the second face.
Example 9 provides the microelectronic assembly of example 8, where: the void includes a substantially continuous void between the first face and the second face.
Example 10 provides the microelectronic assembly of example 8, where: the void includes one or more discontinuities between the first face and the second face, where the conductive material is in contact with the glass at one of the discontinuities.
Example 11 provides the microelectronic assembly of any one of examples 8-10, where: the void has a first width smaller than or equal to about 0.1 microns, where the first width is a first dimension of the void in a plane substantially parallel to the substrate, and the conductive via has a second width in a range of about 50 to 150 microns, where the second width is a second dimension of the conductive via in the plane.
Example 12 provides the microelectronic assembly of any one of examples 8-11, where: an adhesion material is absent from the conductive via between the conductive material and the glass.
Example 13 provides the microelectronic assembly according to any one of examples 1-12, where the microelectronic assembly includes or is a part of a central processing unit.
Example 14 provides the microelectronic assembly according to any one of examples 1-13, where the microelectronic assembly includes or is a part of a memory device.
Example 15 provides the microelectronic assembly according to any one of examples 1-14, where the microelectronic assembly includes or is a part of a logic circuit.
Example 16 provides the microelectronic assembly according to any one of examples 1-15, where the microelectronic assembly includes or is a part of input/output circuitry.
Example 17 provides the microelectronic assembly according to any one of examples 1-16, where the microelectronic assembly includes or is a part of a field programmable gate array transceiver.
Example 18 provides the microelectronic assembly according to any one of examples 1-17, where the microelectronic assembly includes or is a part of a field programmable gate array logic.
Example 19 provides the microelectronic assembly according to any one of examples 1-18, where the microelectronic assembly includes or is a part of a power delivery circuitry.
Example 20 provides an IC package that includes a microelectronic assembly according to any one of examples 1-19.
Example 21 provides the IC package according to example 20, further including a further IC component coupled to the microelectronic assembly.
Example 22 provides the IC package according to example 21, where the further IC component includes a package substrate.
Example 23 provides the IC package according to example 21, where the further IC component includes an interposer.
Example 24 provides the IC package according to example 21, where the further IC component includes a further assembly or die.
Example 25 provides a computing device that includes a carrier substrate and an assembly coupled to the carrier substrate, where the assembly is an assembly according to any one of examples 1-19, or the assembly is included in the IC package according to any one of examples 20-24.
Example 26 provides the computing device according to example 25, where the computing device is a wearable or handheld computing device.
Example 27 provides the computing device according to examples 25 or 26, where the computing device further includes one or more communication chips.
Example 28 provides the computing device according to any one of examples 25-27, where the computing device further includes an antenna.
Example 29 provides the computing device according to any one of examples 25-28, where the carrier substrate is a motherboard
Example 30 provides a method of fabricating a microelectronic assembly, where the method includes providing a first layer of an adhesive material over a second layer of glass, where the second layer of the glass includes a first opening through the glass; forming a second opening through the adhesive material and at least partially aligned with the first opening; bonding a third layer of a first conductive material (e.g., copper foil or other conductive material) with the adhesive material; and depositing a second conductive material on the first conductive material at a bottom of the first opening and in the second opening with an electroplating process (e.g., bottom-up electroplating).
Example 31 provides the method of example 30, where: providing the adhesive material includes bonding an adhesive film with the glass.
Example 32 provides the method of any one of examples 30-31, where: forming the second opening includes forming the second opening with a laser drilling process.
Example 33 provides the method of any one of examples 30-32, where: the second opening has a substantially same width as the first opening.
Example 34 provides the method of any one of examples 30-33, where: bonding the third layer of the first conductive material includes bonding a copper foil to the adhesive material.
Example 35 provides the method of any one of examples 30-34, where: depositing the second conductive material includes depositing the second conductive material in the first opening through the glass without depositing a seed layer on sidewalls of the first opening.
Example 36 provides the method of any one of examples 30-35, where: depositing the second conductive material includes substantially filling the first opening with the second conductive material, where an airgap is present between the second conductive material and the glass at a sidewall of the first opening.
Example 37 provides the method of any one of examples 30-36, further including after depositing the second conductive material: removing the first conductive material, removing the adhesive material, and removing protruding portions of the second conductive material exposed after removal of the first conductive material and the adhesive material.
Example 38 provides a method of fabricating a microelectronic assembly, where the method includes providing a layer of an adhesive material over a layer of a first conductive material (e.g., over the peelable copper foil or other conductive material); forming a first opening in the adhesive material, where the first conductive material is exposed at a bottom of the first opening; bonding a glass substrate with the layer of adhesive, where a second opening in the glass substrate is at least partially aligned with the first opening; and providing a second conductive material in the second opening with an electroplating process (e.g., using the first conductive material exposed through the first opening as a seed).
Example 39 provides the method of example 38, where: providing the second conductive material includes providing the second conductive material on the first conductive material at the bottom of the second opening with the electroplating process.
Example 40 provides the method of any one of examples 38-39, where: providing the second conductive material includes forming one or more air gaps at sidewalls of the second opening between the glass substrate and the second conductive material.
Example 41 provides the method of any one of examples 38-40, where: forming the first opening includes forming the first opening in the adhesive material with a laser etching process.
Example 42 provides the method of any one of examples 38-41, where: the adhesive material includes a photoresist material, and forming the first opening includes forming the first opening with a lithographic process (e.g., forming a mask, expose areas of the adhesive through the mask, and remove exposed areas).
Example 43 provides the method according to any one of examples 30-42, where the microelectronic assembly is a microelectronic assembly according to any one of the preceding examples.
Example 44 provides a process of making a microelectronic assembly according to the method of any one of examples 30-43.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. A microelectronic assembly, comprising:
a layer of glass having a first face and a second face opposite the first face; and
a through-glass via (TGV) in the layer between the first face to the second face, wherein the TGV comprises:
a continuous portion of a conductive material between the first face and the second face, and
an airgap between the conductive material and the glass at a sidewall of the TGV.

2. The microelectronic assembly of claim 1, wherein:
the airgap has a width in a range of about 20 to 100 nanometers, wherein the width is a dimension of the airgap in a plane substantially parallel with the layer.

3. The microelectronic assembly of claim 1, wherein:
the airgap comprises a substantially continuous airgap between the first face and the second face.

4. The microelectronic assembly of claim 1, wherein:
the airgap is one of multiple airgaps between the first face and the second face, wherein the conductive material is in contact with the glass between the airgap and an adjacent airgap.

5. The microelectronic assembly of claim 1, wherein:
in a cross-section of the TGV in a plane substantially parallel with the layer, the airgap surrounds the conductive material.

6. The microelectronic assembly of claim 1, wherein:
the TGV lacks a conductive seed layer on the sidewall.

7. The microelectronic assembly of claim 1, wherein:
a further material is absent from between the sidewall and the conductive material.

8. A microelectronic assembly, comprising:
a substrate comprising a layer of glass, wherein the layer comprises a first face and a second face opposite the first face; and
a conductive via through the layer, wherein the conductive via comprises:
a conductive material between the first face and the second face, wherein the conductive via lacks a seed layer between the conductive material and the glass, and
a void between the conductive material and the glass, wherein the void extends between the first face and the second face.

9. The microelectronic assembly of claim 8, wherein:
the void comprises a substantially continuous void between the first face and the second face.

10. The microelectronic assembly of claim 8, wherein:
the void comprises one or more discontinuities between the first face and the second face, wherein the conductive material is in contact with the glass at one of the discontinuities.

11. The microelectronic assembly of claim 8, wherein:
the void has a first width smaller than or equal to about 0.1 microns, wherein the first width is a first dimension of the void in a plane substantially parallel to the substrate, and
the conductive via has a second width in a range of about 50 to 150 microns, wherein the second width is a second dimension of the conductive via in the plane.

12. The microelectronic assembly of claim 8, wherein:
an adhesion material is absent from the conductive via between the conductive material and the glass.

13. A method of fabricating a microelectronic assembly, wherein the method comprises:
providing a first layer of an adhesive material over a second layer of glass, wherein the second layer of the glass comprises a first opening through the glass;
forming a second opening through the adhesive material and at least partially aligned with the first opening;
bonding a third layer of a first conductive material with the adhesive material; and
depositing a second conductive material on the first conductive material at a bottom of the first opening and in the second opening with an electroplating process.

14. The method of claim 13, wherein:
providing the adhesive material comprises bonding an adhesive film with the glass.

15. The method of claim 13, wherein:
forming the second opening comprises:
forming the second opening with a laser drilling process.

16. The method of claim 13, wherein:
the second opening has a substantially same width as the first opening.

17. The method of claim 13, wherein:
bonding the third layer of the first conductive material comprises:
bonding a copper foil to the adhesive material.

18. The method of claim 13, wherein:
depositing the second conductive material comprises:
depositing the second conductive material in the first opening through the glass without depositing a seed layer on sidewalls of the first opening.

19. The method of claim 13, wherein:
depositing the second conductive material comprises:
substantially filling the first opening with the second conductive material, wherein an airgap is present between the second conductive material and the glass at a sidewall of the first opening.

20. The method of claim 13, further comprising:
after depositing the second conductive material:
removing the first conductive material,
removing the adhesive material, and
removing protruding portions of the second conductive material exposed after removal of the first conductive material and the adhesive material.
